(19) United States
(12) Patent Application Publication
(10) Pub. No.: US 2026/0082584 A1
(43) Pub. Date: Mar. 19, 2026

(54) MEMORY DEVICE

(71) Applicant: Kioxia Corporation, Tokyo (JP)

(72) Inventors: Hyung-Woo AHN, Seongnam-si Gyeonggi-do (KR); Takuya SHIMANO, Seoul (KR); Naoki AKIYAMA, Yokkaichi Mie (JP); Hyungjun CHO, Seongnam-si Gyeonggi-do (KR); Kenichi YOSHINO, Seongnam-si Gyeonggi-do (KR)

(73) Assignee: Kioxia Corporation, Tokyo (JP)

(21) Appl. No.: 19/324,447

(22) Filed: Sep. 10, 2025

(30) Foreign Application Priority Data
Sep. 19, 2024 (JP) 2024-162183

(51) Int. Cl. H10B 61/00; H10N 50/10

(52) U.S. Cl. CPC H10B 61/10; H10N 50/10

(57) ABSTRACT

According to one embodiment, a memory device includes first and second wiring lines and a memory cell between the first and second wiring lines. The memory cell includes a main memory portion including a variable resistance memory element and a switching element, a first electrode between the first wiring line and the main memory portion, and a second electrode between the second wiring line and the main memory portion. At least one of the first and second electrodes includes a structure in which first and second main electrode layers and a sub-electrode layer between the first and second main electrode layers are stacked, and a material of the sub-electrode layer has a higher resistivity than those of materials of the first and second main electrode layers.

### CROSS-REFERENCE TO RELATED APPLICATIONS

This application is based upon and claims the benefit of priority from Japanese Patent Application No. 2024-162183, filed Sep. 19, 2024, the entire contents of which are incorporated herein by reference.

### FIELD

Embodiments described herein relate generally to a memory device.

### BACKGROUND

A memory device in which a plurality of memory cells each including a variable resistance memory element and a selector (a switching element) are integrated on a semiconductor substrate has been proposed.

### BRIEF DESCRIPTION OF THE DRAWINGS

FIG. 1 is a perspective view schematically showing a configuration of a memory device according to the embodiments.

FIG. 2 is a cross-sectional view schematically showing a configuration of the memory device according to the embodiments.

FIG. 3 is a cross-sectional view schematically showing an example of the configuration of a magnetoresistance effect element of the memory device according to the embodiments.

FIG. 4 is a cross-sectional view schematically showing another example of the configuration of the magnetoresistance effect element of the memory device according to the embodiments.

FIG. 5 is a diagram schematically showing current-voltage characteristics of a selector of the memory device according to the embodiments.

FIG. 6 is a cross-sectional view schematically showing a configuration of at least one of a bottom electrode and a top electrode of the memory device according to the embodiments.

FIG. 7 is a cross-sectional view schematically showing a modified example of the configuration of at least one of the bottom electrode and the top electrode of the memory device according to the embodiments.

FIG. 8 is a cross-sectional view schematically showing a modified example of the configuration of the memory device according to the embodiments.

### DETAILED DESCRIPTION

In general, according to one embodiment, a memory device includes: a first wiring line extending in a first direction; a second wiring line extending in a second direction intersecting the first direction; and a memory cell provided between the first wiring line and the second wiring line, wherein the memory cell includes: a main memory portion including a variable resistance memory element and a two-terminal switching element stacked in a third direction intersecting the first and second directions; a first electrode provided between the first wiring line and the main memory portion and connected to the first wiring line and the main memory portion; and a second electrode provided between the second wiring line and the main memory portion and connected to the second wiring line and the main memory portion, at least one of the first electrode and the second electrode includes a structure in which a first main electrode layer, a second main electrode layer, and a sub-electrode layer provided between the first main electrode layer and the second main electrode layer are stacked in the third direction, and a material of the sub-electrode layer has a higher resistivity than that of a material of the first main electrode layer and that of a material of the second main electrode layer.

Hereinafter, an embodiment will be described with reference to the accompanying drawings.

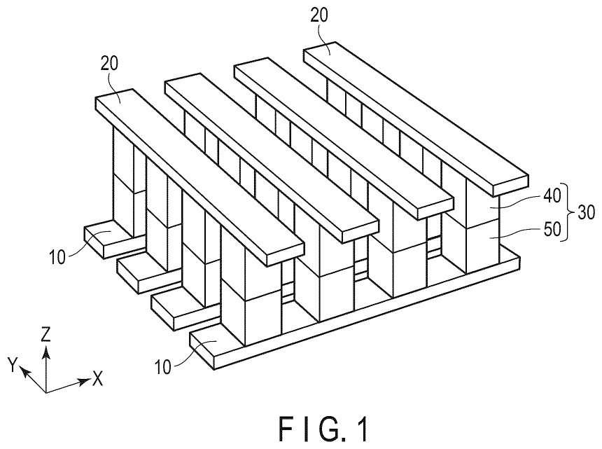

FIG. 1 is a perspective view schematically showing a configuration of a memory device according to the embodiments.

The memory device according to the present embodiment is provided on an under region (not shown) including a semiconductor substrate (not shown).

The memory device includes a plurality of lower wiring lines 10 (one of the first wiring line and the second wiring line) each extending in the X-direction, a plurality of upper wiring lines 20 (the other of the first wiring line and the second wiring line) each extending in the Y-direction, and a plurality of memory cells 30 provided between the plurality of lower wiring lines 10 and the plurality of upper wiring lines 20.

One of the lower wiring line 10 and the upper wiring line 20 corresponds to a word line. The other corresponds to a bit line.

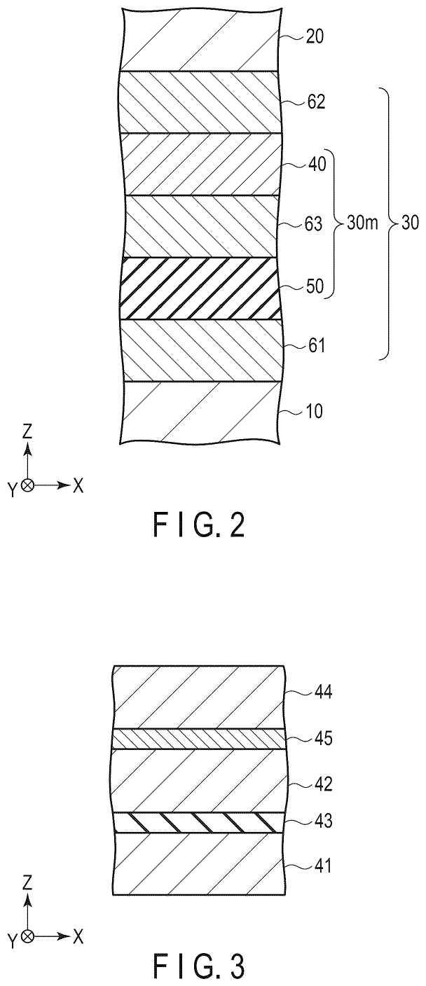

FIG. 2 is a cross-sectional view schematically showing a configuration of the memory device according to the present embodiment.

As shown in FIG. 2, a memory cell 30 includes a main memory portion 30m, a bottom electrode 61 (one of the first electrode and the second electrode), and a top electrode 62 (the other electrode).

The main memory portion 30m, the bottom electrode 61, and the top electrode 62 are stacked in the Z-direction.

The main memory portion 30m functions as the actual memory portion of the memory cell 30.

The main memory portion 30m includes a magnetoresistance effect element 40, which is a nonvolatile variable resistance memory element (referred to as a magnetoresistance effect element body as well, and in the following explanations, the magnetoresistance effect element is adopted as the variable resistance memory element.), a selector 50, which is a two-terminal switching element, and a middle electrode 63 (the third electrode) provided between the magnetoresistance effect element 40 and the selector 50.

The magnetoresistance effect element 40, the selector 50, and the middle electrode 63 are stacked in the Z-direction.

The magnetoresistance effect element 40 and the selector 50 are connected in series via the middle electrode 63.

The bottom electrode 61 is provided between the lower wiring line 10 and the main memory portion 30m and is connected to the lower wiring lines 10 and the main memory portion 30m.

The top electrode 62 is provided between the upper wiring line 20 and the main memory portion 30m and is connected to the upper wiring line 20 and the main memory portion 30m.

Note that the X-direction, the Y-direction, and the Z-direction intersect one another. More specifically, the X-direction, the Y-direction, and the Z-direction are orthogonal to one another.

FIG. 3 is a cross-sectional view schematically showing an example of the configuration of the magnetoresistance effect element 40.

The magnetoresistance effect element 40 is Magnetic Tunnel Junction (MTJ) element comprising a storage layer 41 (the first magnetic layer), a reference layer 42 (the second magnetic layer), a tunnel barrier layer 43 (a nonmagnetic layer), a shift-canceling layer 44 (the third magnetic layer), and an intermediate layer 45. The magnetoresistance effect element 40 has a structure in which these layers 41 to 45 are stacked in the Z-direction.

The storage layer 41 is a ferromagnetic layer having a variable magnetization direction, and is formed, for example, by a CoFeB layer containing cobalt (Co), iron (Fe), and boron (B). The variable magnetization direction means that a magnetization direction changes for a predetermined write current.

The reference layer 42 is a ferromagnetic layer having a fixed magnetization direction, and is formed, for example, by the CoFeB layer containing cobalt (Co), iron (Fe), and boron (B). The fixed magnetization direction means that a magnetization direction does not change for a predetermined write current.

The tunnel barrier layer 43 is an insulating layer provided between the storage layer 41 and the reference layer 42, and is formed, for example, by an MgO layer containing magnesium (Mg) and oxygen (O).

The shift-canceling layer 44 is a ferromagnetic layer having the fixed magnetization direction antiparallel to the magnetization direction of the reference layer 42 and has the function of canceling the magnetic field applied from the reference layer 42 to the storage layer 41. The shift-canceling layer 44 is formed, for example, by a superlattice layer in which cobalt (Co) and platinum (Pt) are alternately stacked.

The intermediate layer 45 is provided between the reference layer 42 and the shift-canceling layer 44 and is formed, for example, by a ruthenium (Ru) layer.

When the magnetization direction of the storage layer 41 is parallel to the magnetization direction of the reference layer 42, the magnetoresistance effect element 40 is in a low-resistance state with a relatively low resistance.

When the magnetization direction of the storage layer 41 is antiparallel to the magnetization direction of the reference layer 42, the magnetoresistance effect element 40 is in a high-resistance state with a relatively high resistance. Thus, the magnetoresistance effect element 40 can store binary data according to its resistance states.

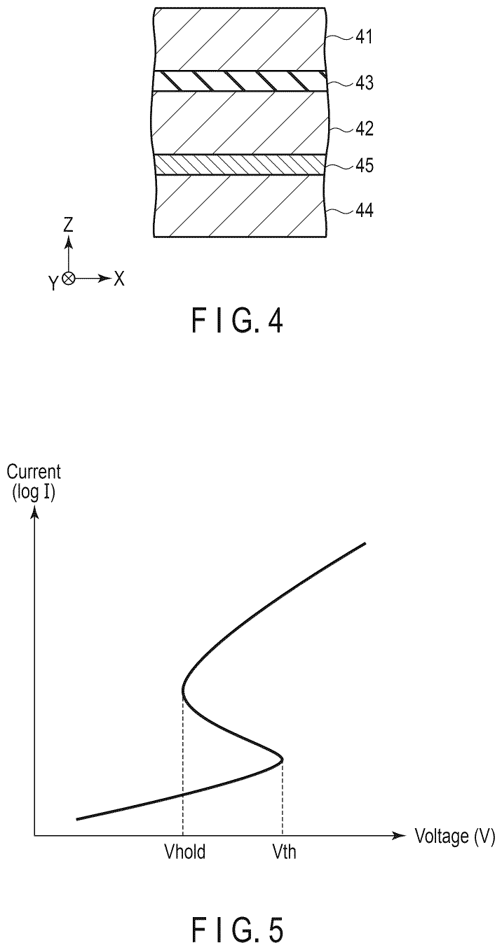

FIG. 4 is a cross-sectional view schematically showing another example of the configuration of the magnetoresistance effect element 40.

The magnetoresistance effect element 40 shown in FIG. 3 is a bottom-free type magnetoresistance effect element with the storage layer 41 located on the lower layer side of the reference layer 42. On the other hand, the magnetoresistance effect element 40 shown in FIG. 4 is a top-free type magnetoresistance effect element with the storage layer 41 located on the upper layer side of the reference layer 42. The stacking order of the layers 41 to 45 of the magnetoresistance effect element 40 shown in FIG. 4 is reversed with respect to that shown in FIG. 3.

The magnetoresistance effect element 40 shown in FIG. 4 may be used instead of the magnetoresistance effect element 40 shown in FIG. 3.

What follows is additional explanations on FIG. 2. The selector 50 includes a selector material layer (a switching material layer) formed of materials described later and has a switching function. In the example shown in FIG. 2, the selector 50 substantially corresponds to the selector material layer, the bottom electrode 61 functions as the bottom electrode of the selector, and the middle electrode 63 functions as the top electrode of the selector.

FIG. 5 is a diagram schematically showing the current-voltage characteristic of the selector 50.

The selector 50 has the characteristic of changing from the off state to the on state when the voltage applied between the two terminals reaches or exceeds a threshold voltage Vth and changing from the on state to the off state when the voltage applied between the two terminals becomes equal to or less than a hold voltage Vhold. In the example of FIG. 2, the voltage applied between the two terminals corresponds to the voltage applied between the bottom electrode 61 and the middle electrode 63.

When a voltage is applied between the lower wiring line 10 and the upper wiring line 20 and the voltage applied to the selector 50 exceeds the threshold voltage Vth, the selector 50 changes from the off state to the on state. In the on state, write or read can be performed on the magnetoresistance effect element 40 connected to the selector 50 in series.

The selector material layer of the selector 50 is preferably formed of a material selected from any of a material containing silicon (Si) and oxygen (O), a material containing silicon (Si) and nitrogen (N), a material containing hafnium (Hf) and oxygen (O), a material containing tantalum (Ta) and oxygen (O), a material containing titanium (Ti) and oxygen (O), a material containing tungsten (W) and oxygen (O), a material containing zirconium (Zr) and oxygen (O), a material containing aluminum (Al) and oxygen (O), a material containing nickel (Ni) and oxygen (O), a material containing niobium (Nb) and oxygen (O), a material containing arsenic (As) and sulfur(S), a material containing zinc (Zn) and tellurium (Te), a material containing germanium (Ge) and selenium (Se), a material containing germanium (Ge) and arsenic (As), a material containing germanium (Ge) and tellurium (Te), a material containing carbon (C) and tellurium (Te), and a material containing arsenic (As) and tellurium (Te).

More specifically, the selector material layer of the selector 50 is preferably selected from any of an SiO layer, an SiN layer, an SiON layer, an AsSiO layer, an AsSiOTi layer, an AsSiOTiN layer, an AsSiOTiNC layer, an HfO layer, an AsHfO layer, a TaO layer, a TiO layer, a WO layer, a ZrO layer, an AlO layer, an NiO layer, an NbO layer, an AsS layer, a ZnTe layer, an AsZnTe layer, an SiZnTe layer, an AsSiZnTe layer, a GeSe layer, a GeAsSeTe layer, a GeAs layer, a GeTe layer, a CTe layer, an SiAsTe layer, an SiGeAsTe layer, a GeAsTe layer, an AsTe layer, and an SiGeAsSe layer.

The selector material layer may further contain at least one element selected from carbon (C), nitrogen (N), indium (In), and boron (B).

At least one of the bottom electrode 61 and the top electrode 62 has a structure in which a first main electrode layer, a second main electrode layer, and a sub-electrode layer provided between the first main electrode layer and the second main electrode layer are stacked in the Z-direction. That is, either or both of the bottom electrode 61 and the top electrode 62 have such a stacked structure. The material of the sub-electrode layer has the resistivity higher than those of the materials of the first main electrode layer and the second main electrode layer.

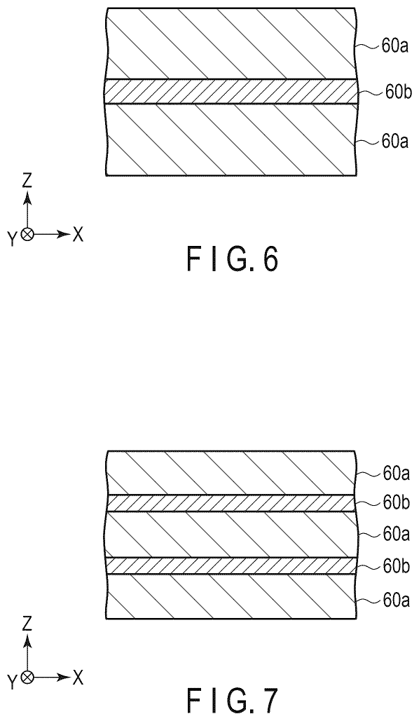

FIG. 6 is a cross-sectional view schematically showing the configuration of at least one of the bottom electrode 61 and the top electrode 62.

In the example shown in FIG. 6, at least one of the bottom electrode 61 and the top electrode 62 includes two main electrode layers 60a (the first and second main electrode layers) and one sub-electrode layer 60b provided between the two main electrode layers 60. That is, the sub-electrode layer 60b is interposed between the two main electrode layers 60a.

The main electrode layers 60a preferably contain at least one element selected from carbon (C), titanium (Ti), tantalum (Ta), and tungsten (W). The main electrode layers 60a may additionally contain at least one element selected from nitrogen (N) and silicon (Si).

More specifically, the main electrode layer 60a is preferably selected from a C layer, a CN layer, a Ti layer, a Ta layer, a TiN layer, a TaN layer, a TiCN layer, a TiAlN layer, a W layer, a WN layer, a WSi layer, and a WSiN layer.

The two main electrode layers 60a are typically formed of the same material, but may be formed of different materials.

As described above, the material of the sub-electrode layer 60b has a higher resistivity than that of the main electrode layer 60a. The sub-electrode layer 60b preferably contains at least one of a metal element and a semiconductor element, and at least one of oxygen (O) and nitrogen (N).

The metal element and semiconductor element contained in the sub-electrode layer 60b are preferably selected from any of tungsten (W), silicon (Si), aluminum (Al), titanium (Ti), indium (In), tantalum (Ta), hafnium (Hf), zinc (Zn), ruthenium (Ru), tin (Sn), magnesium (Mg), zirconium (Zr), and chromium (Cr).

More specifically, the sub-electrode layer 60b is preferably selected from a WSiN layer, a WSiO layer, an SiN layer, an SiO layer, an AlO layer, a TiN layer, an InO layer, a WN layer, a TaN layer, an HfO layer, a ZnO layer, an RuO layer, an SnO layer, an MgO layer, a ZrN layer, a CrN layer, an AlN layer, and an HfN layer.

The sub-electrode layer 60b may further contain at least one element selected from nickel (Ni), molybdenum (Mo), vanadium (V), carbon (C), boron (B), phosphorus (P), and sulfur(S).

As described above, in the present embodiment, at least one of the bottom electrode 61 and the top electrode 62 includes a structure in which two main electrode layers 60a and the sub-electrode layer 60b, provided between the two main electrode layers 60a, are stacked. The material of the sub-electrode layer 60b has a higher resistivity than that of the main electrode layer 60a. As described below, this configuration of the present embodiment can prevent excessive current from flowing through the memory cell 30.

As described above, when the voltage applied to the selector 50 reaches or exceeds the threshold voltage Vth, the selector 50 changes from the off state to the on state. In the on state, write or read can be performed on the magnetoresistance effect element 40 connected to the selector 50 in series. However, when the selector 50 changes from the off state to the on state, the resistance of the selector 50 decreases sharply, causing the overall resistance of the memory cell 30 to decrease sharply as well. This may cause excessive current, such as spike current, to flow through the memory cell 30. Excessive current flowing through the memory cell 30 in this manner may deteriorate characteristics and reliability of the memory cell 30.

In the present embodiment, at least one of the bottom electrode 61 and the top electrode 62 includes the sub-electrode layer 60b formed of a material having a higher resistivity than that of the main electrode layer 60a. Thus, even if the resistance of the selector 50 decreases sharply when the selector 50 changes from the off state to the on state, this configuration with the sub-electrode layer 60b having high resistance can suppress the sharp decrease in the overall resistance of the memory cell 30. Thus, the present embodiment can suppress excessive current flowing through the memory cell 30 at time of the selector 50 changing from the off state to the on state, preventing the characteristics and the reliability of the memory cell 30 from deteriorating.

FIG. 7 is a cross-sectional view schematically showing a modified example of the configuration of at least one of the bottom electrode 61 and the top electrode 62.

As shown in FIG. 7, at least one of the bottom electrode 61 and the top electrode 62 may include three or more main electrode layers 60a and two or more sub-electrode layers 60b. Each of the sub-electrode layers 60b is provided between adjacent main electrode layers 60a (the first and second main electrode layers).

The three or more main electrode layers 60a are typically formed of the same material. Some of them may be formed of different materials. Similarly, the two or more sub-electrode layers 60b are typically formed of the same material. Some of them may be formed of different materials.

Even when the electrode configuration shown in FIG. 7 is adopted, the same effects as those described above can be achieved.

Furthermore, at least one of the bottom electrode 61 and the top electrode 62 may have the electrode configuration shown in FIG. 6 and FIG. 7, and the middle electrode 63 may also have the electrode configuration shown in FIG. 6 and FIG. 7.

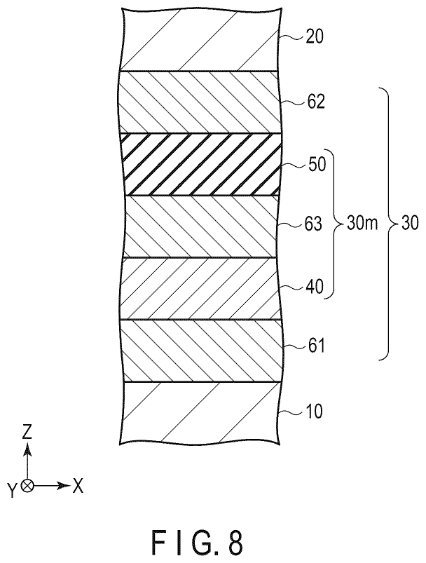

FIG. 8 is a cross-sectional view schematically showing a modified configuration of the memory device according to the present embodiment.

In the above-described embodiment, as shown in FIG. 2, the magnetoresistance effect element 40 is provided on the upper layer side of the selector 50, the magnetoresistance effect element 40 is connected to the top electrode 62, and the selector 50 is connected to the bottom electrode 61. In the modified example, as shown in FIG. 8, the magnetoresistance effect element 40 is provided on the lower layer side of the selector 50, the magnetoresistance effect element 40 is connected to the bottom electrode 61, and the selector 50 is connected to the top electrode 62.

The basic configuration of the modified example is the same as that of the above-described embodiment. The modified example can achieve the same effects as those described above.

Although the magnetoresistance effect elements are adopted as the variable resistance memory elements in the above embodiments, other variable resistance type memory elements may be adopted as the variable resistance memory elements.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is

1. A memory device comprising:
a first wiring line extending in a first direction;
a second wiring line extending in a second direction intersecting the first direction; and
a memory cell provided between the first wiring line and the second wiring line,
wherein
the memory cell includes:
a main memory portion including a variable resistance memory element and a two-terminal switching element stacked in a third direction intersecting the first and second directions;
a first electrode provided between the first wiring line and the main memory portion and connected to the first wiring line and the main memory portion; and
a second electrode provided between the second wiring line and the main memory portion and connected to the second wiring line and the main memory portion,
at least one of the first electrode and the second electrode includes a structure in which a first main electrode layer, a second main electrode layer, and a sub-electrode layer provided between the first main electrode layer and the second main electrode layer are stacked in the third direction, and
a material of the sub-electrode layer has a higher resistivity than that of a material of the first main electrode layer and that of a material of the second main electrode layer.

2. The memory device of claim 1, wherein
each of the first and second main electrode layers contains at least one element selected from carbon (C), titanium (Ti), tantalum (Ta), and tungsten (W).

3. The memory device of claim 2, wherein
each of the first and second main electrode layers further contains at least one element selected from nitrogen (N) and silicon (Si).

4. The memory device of claim 1, wherein
each of the first and second main electrode layers is selected from a C layer, a CN layer, a Ti layer, a Ta layer, a TiN layer, a TaN layer, a TiCN layer, a TiAlN layer, a W layer, a WN layer, a WSi layer, and a WSiN layer.

5. The memory device of claim 1, wherein
the sub-electrode layer contains at least one of a metal element and a semiconductor element and at least one of oxygen (O) and nitrogen (N).

6. The memory device of claim 5, wherein
the metal element and the semiconductor element are selected from tungsten (W), silicon (Si), aluminum (Al), titanium (Ti), indium (In), tantalum (Ta), hafnium (Hf), zinc (Zn), ruthenium (Ru), tin (Sn), magnesium (Mg), zirconium (Zr), and chromium (Cr).

7. The memory device of claim 1, wherein
the sub-electrode layer is selected from a WSiN layer, a WSiO layer, an SiN layer, an SiO layer, an AlO layer, a TiN layer, an InO layer, a WN layer, a TaN layer, an HfO layer, a ZnO layer, an RuO layer, an SnO layer, an MgO layer, a ZrN layer, a CrN layer, an AlN layer, and an HfN layer.

8. The memory device of claim 1, wherein
the switching element includes a switching material layer formed of a material selected from a material containing silicon (Si) and oxygen (O), a material containing silicon (Si) and nitrogen (N), a material containing hafnium (Hf) and oxygen (O), a material containing tantalum (Ta) and oxygen (O), a material containing titanium (Ti) and oxygen (O), a material containing tungsten (W) and oxygen (O), a material containing zirconium (Zr) and oxygen (O), a material containing aluminum (Al) and oxygen (O), a material containing nickel (Ni) and oxygen (O), a material containing niobium (Nb) and oxygen (O), a material containing arsenic (As) and sulfur(S), a material containing zinc (Zn) and tellurium (Te), a material containing germanium (Ge) and selenium (Se), a material containing germanium (Ge) and arsenic (As), a material containing germanium (Ge) and tellurium (Te), a material containing carbon (C) and tellurium (Te), and a material containing arsenic (As) and tellurium (Te).

9. The memory device of claim 8, wherein
the switching material layer is selected from an SiO layer, an SiN layer, an SiON layer, an AsSiO layer, an AsSiOTi layer, an AsSiOTiN layer, an AsSiOTiNC layer, an HfO layer, an AsHfO layer, a TaO layer, a TiO layer, a WO layer, a ZrO layer, an AlO layer, an NiO layer, an NbO layer, an AsS layer, a ZnTe layer, an AsZnTe layer, an SiZnTe layer, an AsSiZnTe layer, a GeSe layer, a GeAsSeTe layer, a GeAs layer, a GeTe layer, a CTe layer, an SiAsTe layer, an SiGeAsTe layer, a GeAsTe layer, an AsTe layer, and an SiGeAsSe layer.

10. The memory device of claim 1, wherein
one of the first electrode and the second electrode is connected to the variable resistance memory element, and the other is connected to the switching element.

11. The memory device of claim 1, wherein
the main memory portion further includes a third electrode provided between the variable resistance memory element and the switching element.

12. The memory device of claim 1, wherein
the variable resistance memory element is a magnetoresistance effect element.

13. The memory device of claim 1, wherein
the switching element has a characteristic of changing from an off state to an on state when voltage applied between two terminals thereof reaches or exceeds a threshold voltage.

14. The memory device of claim 1, wherein
when the switching element is in an on state by applying voltage between the first wiring line and the second wiring line, write or read can be performed on the variable resistance memory element.
